(19) United States
(12) Patent Application Publication
(10) Pub. No.: US 2025/0157850 A1
(43) Pub. Date: May 15, 2025

(54) STAGE MOTION PROFILE SYSTEM AND METHOD

(71) Applicant: KLA Corporation, Milpitas, CA (US)

(72) Inventors: Zhaolong Shen, Irvine, CA (US); Mike Chen, Washougal, WA (US); Lior Kabesa, San Jose, CA (US)

(73) Assignee: KLA Corporation, Milpitas, CA (US)

(21) Appl. No.: 18/388,405

(22) Filed: Nov. 9, 2023

(51) Int. Cl. H01L 21/687; H01L 21/67

(52) U.S. Cl. CPC H01L 21/68764; H01L 21/67259

(57) ABSTRACT

A system for generating a motion profile is disclosed. The system includes a controller. The controller receives a target position for a stage. The controller generates a motion profile for transitioning the stage to the target position. The motion profile includes an acceleration profile having one or more segments that vary as a function of time. The controller modifies the segments of the acceleration profile by: determining a midpoint for each segment, determining a reference line for each segment with a slope that is greater than the corresponding segment, dividing each segment into a first sub-segment and a second sub-segment, defining the first sub-segment as a function such that a starting point is tangential to a first axis and an ending point is tangential to the reference line, defining the second sub-segment by rotating the first sub-segment about the midpoint, and actuating the stage in response to the motion profile.

### TECHNICAL FIELD

The present disclosure relates generally to motion control systems used in semiconductor manufacturing equipment and, more particularly, to a system and method for implementing poly seven-segment motion profiles for a wafer handling stage.

### BACKGROUND

The precise and efficient handling of semiconductor wafers during manufacturing processes is essential for ensuring high-quality electronic devices. One critical challenge in wafer handling stages and other motion control systems is the reduction of vibrations caused by acceleration and deceleration. These vibrations not only impact the performance of the wafer handling stage but also affect the overall throughput of the tool or machine.

Conventional motion control methods have relied on the standard 7-segment design, which divides the motion trajectory into a maximum of seven phases, each governed by constraints on maximal jerk, acceleration, and velocity. While the 7-segment method provides a straightforward approach for controlling motion, it has inherent disadvantages. One major drawback is the sharp change in acceleration profiles between segments. This abrupt transition introduces shocks and high-frequency components into the stage, leading to mechanical vibrations that can negatively impact the wafer handling process. There is therefore a need to develop systems and methods to cure the above deficiencies.

### SUMMARY

A system is disclosed, in accordance with one or more illustrative embodiments of the present disclosure. In one illustrative embodiment, the system includes a controller configured to modify a motion profile for a stage of a semiconductor tool. In another illustrative embodiment, the controller comprises one or more processors configured to execute program instructions stored in memory. In another illustrative embodiment, the one or more processors are configured to receive at least a target position for the stage. In another illustrative embodiment, the one or more processors are configured to generate a motion profile for transitioning the stage to the target position, where the motion profile includes an acceleration profile having one or more segments that vary as a function of time. In another illustrative embodiment, the one or more processors are configured to modify the one or more segments of the acceleration profile by: determining a midpoint for each of the one or more segments; determining a reference line for each of the one or more segments, the reference line configured to bisect a corresponding segment and have a slope greater than the slope of the corresponding segment; dividing each of the one or more segments into at least a first sub-segment and a second sub-segment; defining the first sub-segment as a function such that a starting point is tangential to a first axis and an ending point is tangential to the reference line; defining the second sub-segment by rotating the first sub-segment about the midpoint by a selected angle of rotation; and actuating the stage to the target position based on the generated motion profile.

A semiconductor characterization system is disclosed, in accordance with one or more illustrative embodiments of the present disclosure. In one illustrative embodiment, the system includes a stage of a semiconductor tool. In another illustrative embodiment, the system includes a controller configured to modify a motion profile for the stage of the semiconductor tool. In another illustrative embodiment, the controller comprises one or more processors configured to execute program instructions stored in memory. In another illustrative embodiment, the one or more processors are configured to receive at least a target position for the stage. In another illustrative embodiment, the one or more processors are configured to generate a motion profile for transitioning the stage to the target position, where the motion profile includes an acceleration profile having one or more segments that vary as a function of time. In another illustrative embodiment, the one or more processors are configured to modify the one or more segments of the acceleration profile by: determining a midpoint for each of the one or more segments; determining a reference line for each of the one or more segments, the reference line configured to bisect a corresponding segment and have a slope greater than the slope of the corresponding segment; dividing each of the one or more segments into at least a first sub-segment and a second sub-segment; defining the first sub-segment as a function such that a starting point is tangential to a first axis and an ending point is tangential to the reference line; defining the second sub-segment by rotating the first sub-segment about the midpoint by a selected angle of rotation; and actuating the stage to the target position based on the generated motion profile.

A method for generating a motion profile is disclosed, in accordance with one or more embodiments of the present disclosure. In one illustrative embodiment, the method may include, but is not limited to, receiving at least a target position for a stage of a semiconductor tool. In another illustrative embodiment, the method may include, but is not limited to, generating a motion profile for transitioning the stage to the target position, where the motion profile includes an acceleration profile having one or more segments that vary as a function of time. In another illustrative embodiment, the method may include, but is not limited to, modifying, via one or more processors, the one or more segments of the acceleration profile by: determining a midpoint for each of the one or more segments; determining a reference line for each of the one or more segments, the reference line configured to bisect a corresponding segment and have a slope greater than the slope of the corresponding segment; dividing each of the one or more segments into at least a first sub-segment and a second sub-segment; defining the first sub-segment as a function such that a starting point is tangential to a first axis and an ending point is tangential to the reference line; defining the second sub-segment by rotating the first sub-segment about the midpoint by a selected angle of rotation; and actuating the stage to at least the target position in response to the modified acceleration profile.

It is to be understood that both the foregoing general description and the following detailed description are exemplary and explanatory only and are not necessarily restrictive of the invention as claimed. The accompanying drawings, which are incorporated in and constitute a part of the specification, illustrative embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A is a conceptual view of a motion profile system used, in accordance with one or more embodiments of the present disclosure.

FIG. 1B is a conceptual view of a semiconductor characterization tool 116 utilizing the motion profile system, in accordance with one or more embodiments of the present disclosure.

FIG. 1C is a top view illustrating a double gantry stage configured for bidirectional motion control, in accordance with one or more embodiments of the present disclosure.

FIG. 2 is a comparison of an acceleration profile generated by the motion profile system with a standard 7-segment motion profile, in accordance with one or more embodiments of the present disclosure.

FIG. 3 is a comparison of a segment of the acceleration profile generated by the motion profile system with a segment of the standard 7-segment motion profile, in accordance with one or more embodiments of the present disclosure.

FIG. 4 is a flow diagram depicting a method for generating an acceleration profile for a wafer handling stage, in accordance with one or more embodiments of the present disclosure.

FIG. 5 is a flow diagram depicting a method for modifying one or more segments of the generated acceleration profile for the semiconductor stage, in accordance with one or more embodiments of the present disclosure.

FIGS. 6A-6B illustrate swath performance metrics of the motion profile system compared to a standard 7-segment motion profile, in accordance with one or more embodiments of the present disclosure.

FIGS. 7A-7B illustrate final position error metrics of the motion profile system compared to a standard 7-segment motion profile, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods for generating a smooth multi-segment motion profile for a stage of a semiconductor tool. The smooth multi-segment motion profile includes one or more segments, with each segment having similar or analogous timing and position as a standard 7-segment motion profile. In contrast to the standard 7-segment motion profile, the motion profile may be modified such that each segment is divided into two sub-segments defined by functions that help to smooth the motion profile.

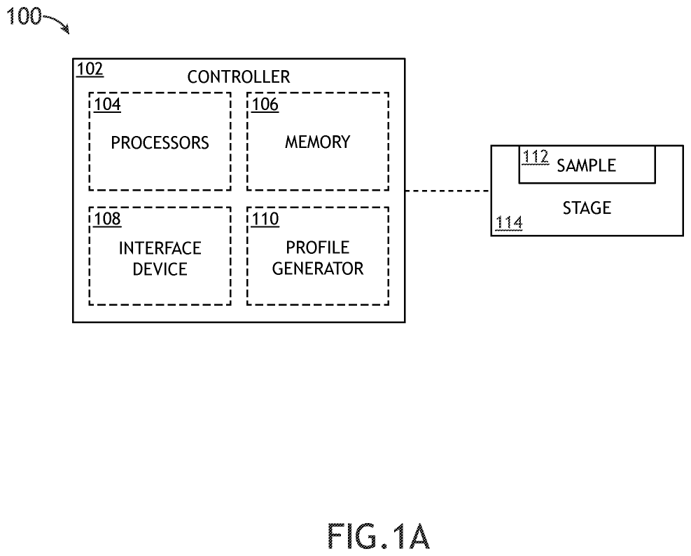

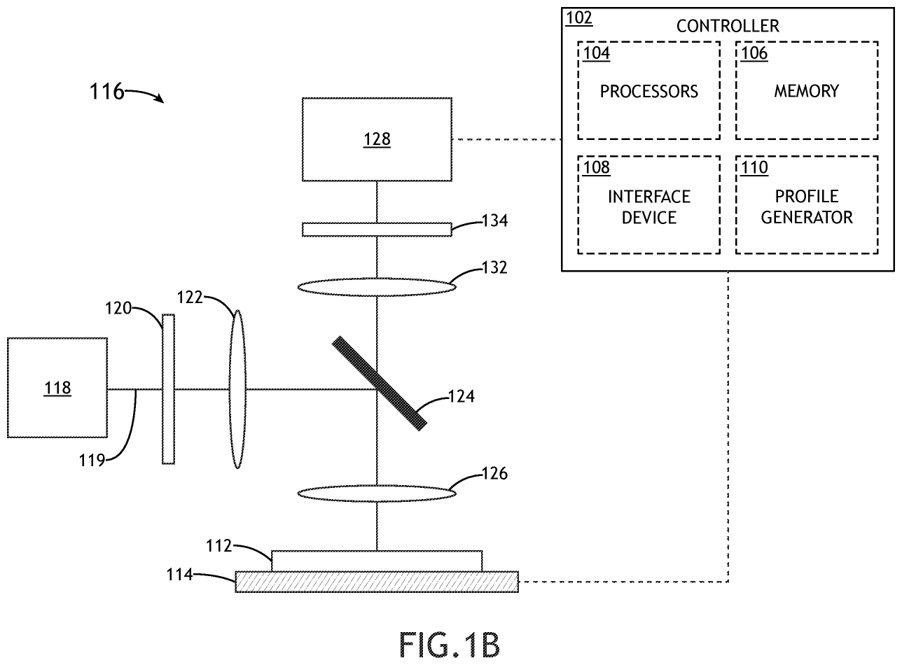

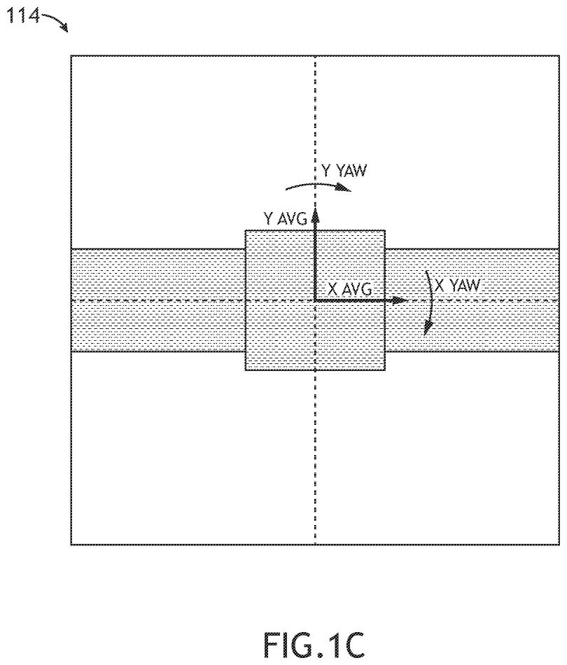

Referring now to FIGS. 1-7B, systems and methods for motion profile generation are described in greater detail, in accordance with one or more embodiments of the present disclosure.

FIG. 1A is a conceptual view of a motion profile system 100 capable of generating motion profiles for a stage 114, in accordance with one or more embodiments of the present disclosure.

In embodiments, the motion profile system 100 includes a controller 102. For example, the controller 102 may include one or more processors 104, a memory medium 106 (e.g., medium), an interface device 108, and a profile generator 110. By way of another example, the profile generator 110 may be configured to generate one of more of a position profile, a velocity profile, and/or an acceleration profile. In embodiments, one or more of the one or more processors 104, memory medium 106, interface device 108, and/or the profile generator 110 may be electrically and/or communicatively coupled to one another to perform one or more of the functions of the motion profile system 100.

In embodiments, the interface device 108 may be configured to receive a user input and to render output to the user in any suitable format (e.g., visual, audio, tactile, etc.). User input may include, for example, user entered constraints (e.g., maximum acceleration, maximum velocity, etc.) used by the profile generator 110 to calculate a motion profile.

In embodiments, the profile generator 110 may be configured to receive an indication of a desired target position for the stage 114 and calculate a motion profile for transitioning the stage 114 to the target position within the parameters of the user defined constraints.

In embodiments, the profile generator 110 may integrate with the controller 102. For example, the profile generator 110 may be configured as a functional component of the operating system of controller 102 and/or the control software, which is executed by the one or more processors 104. By way of another example, the profile generator 110 may be implemented as a hardware component within the controller 102, such as a circuit board or integrated circuit, that exchanges data with other functional elements of the controller 102. It should be understood that other embodiments of the profile generator 110 are also encompassed within the scope of this disclosure. For instance, the profile generator 110 may be configured as a separate element from the controller 102, with the capability to exchange data with the controller 102 or other elements of the motion profile system 100 via various communication means including, but not limited to, wired or wireless networking, hardwired data links, or other suitable communication methods known in the art.

The one or more processors 104 of the controller 102 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors 104 (DSPs)). In this sense, the one or more processors 104 may include any device configured to execute algorithms and/or instructions (e.g., program instructions stored in memory 106). In embodiments, the one or more processors 104 may be embodied as a desktop computer, mainframe computer system, workstation, image computer, parallel processor, networked computer, or any other computer system configured to execute a program configured to operate or operate in conjunction with the motion profile system 100, as described throughout the present disclosure. It is noted that the one or more processors 104 of the controller 102 may execute any of the various process steps described throughout the present disclosure.

Moreover, different subsystems of the motion profile system 100 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller 102 or, alternatively, multiple controllers 102. Additionally, the controller 102 may include one or more controllers housed in a common housing or within multiple housings. In this way, any controller 102 or combination of controllers may be separately packaged as a module suitable for integration into the motion profile system 100.

The memory medium 106 may include any storage medium known in the art suitable for storing program instructions executable by the associated one or more processors 104. For example, the memory medium 106 may include a non-transitory memory medium 106. By way of another example, the memory medium 106 may include, but is not limited to, a read-only memory (ROM), a random-access memory (RAM), a magnetic or optical memory device (e.g., disk), a magnetic tape, a solid-state drive and the like. It is further noted that memory medium 106 may be housed in a common controller housing with the one or more processors 104. In embodiments, the memory medium 106 may be located remotely with respect to the physical location of the one or more processors 104 and controller 102. For instance, the one or more processors 104 of controller 102 may access a remote memory 106 (e.g., server), accessible through a network (e.g., internet, intranet, and the like).

FIG. 1B illustrates a conceptual view of semiconductor characterization tool 116 utilizing the motion profile system 100, in accordance with one or more embodiments of the present disclosure. The characterization tool 116 may be configured as any optical characterization tool known in the art including, but not limited to, an inspection tool or a metrology tool.

In embodiments, the controller 102 may be communicatively coupled to the stage 114 to adjust a position and/or an orientation of the stage 114 in response to a generated motion profile. For example, the stage 114 may include any number of linear and/or rotational actuators to actuate the sample 112. Examples of wafer characterization tools are described in detail in U.S. Pat. Nos. 7,092,082, 6,702,302, 6,621,570 and 5,805,278, each of which are incorporated herein by reference in the entirety.

In embodiments, the characterization tool 116 may include an illumination source 118 configured to generate illumination beam 119. For example, the illumination source 118 may direct the illumination beam 119 to sample 112 disposed on stage 114 via an illumination pathway. The illumination pathway may include one or more illumination-pathway focusing elements 122 or additional illumination-pathway optical components 120 suitable for modifying and/or conditioning the illumination beam 119. Further, the characterization tool 116 may include an objective lens 126 to focus or otherwise direct the illumination beam 119 onto the sample 112.

In embodiments, the characterization tool 116 may include a detector 128 configured to capture radiation emanating from the sample 112 through a collection pathway. For example, a detector 128 may receive an image of the sample 112 provided by elements in the collection pathway (e.g., the objective lens 126, one or more collection-pathway focusing elements 132, or the like). The collection pathway 130 may further include any number of collection-pathway optical elements 134 to direct and/or modify illumination collected by the objective lens 126 including, but not limited to, one or more filters, one or more polarizers, or one or more beam blocks. The detector 128 may include any type of optical detector known in the art suitable for measuring illumination received from the sample 112.

In embodiments, as shown in FIG. 1C, the stage 114 may include a double gantry stage 114. For example, the double gantry stage 114 may be configured to provide bidirectional motion control for the sample 112. The double gantry stage 114 may include an X-axis gantry positioned perpendicular to a Y-axis gantry. It is noted herein that the motion profile system 100 is not limited to a specific stage-type and may include one or more adjustable stages 114 such as, but not limited to, a double gantry stage, a linear translation stage, a rotational stage, a tip/tilt stage, or the like.

In embodiments, the double gantry stage 114, may include one or more characteristics related to the positioning and alignment of the stage 114. For example, X_{yaw} may refer to the yaw or angular deviation in the X-axis (horizontal) direction. By way of another example, Y_{yaw} may represent the yaw or angular deviation in the Y-axis (vertical) direction. These measurements may indicate how well the stage 114 maintains its orientation in the X and Y directions while moving or positioning in response to a received motion profile from the motion profile system 100. Yaw errors can lead to misalignment or skewed positioning of the stage 114, which is a critical parameter to maintain in applications that require high precisions such as the motion profile system 100. By way of another example, X_{AVG} may refer to the average or mean position error in the X-axis direction. It represents how far, on average, the stage 114 deviates from its desired X-axis position. By way of another example, the Y_{AVG} similarly represents the average or mean position error in the Y-axis direction. These measurements may provide information about the overall accuracy of the stage 114 in achieving a target position, determined by the generated motion profile of the system 100, along the X and Y axes.

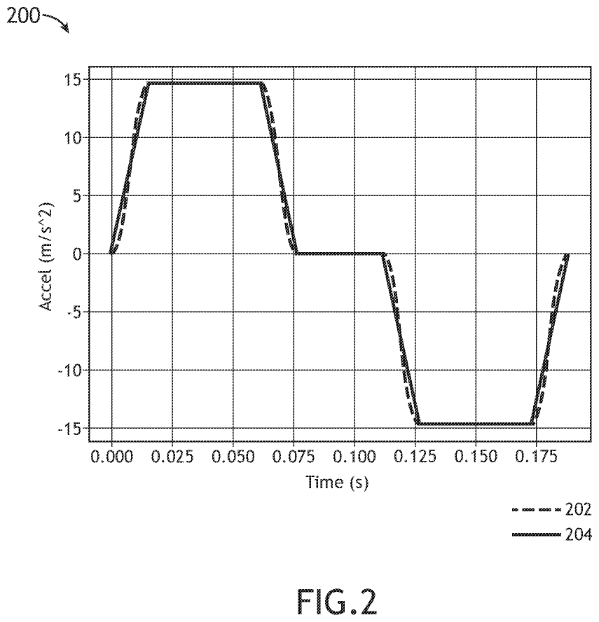

FIG. 2 illustrates a comparison 200 of an acceleration profile 202 generated by the motion profile system 100 with a standard 7-segment motion profile 204, in accordance with one or more embodiments of the present disclosure.

In embodiments, the motion profile system 100 may include an acceleration profile 202. The acceleration profile 202 may be representative of an acceleration domain of the motion profile generated by the system 100. For example, the acceleration domain may refer to the specific phase(s) or segment(s) of the motion profile where acceleration is the primary parameter that is changing. By way of another example, the acceleration profile 202 may be defined by at least one of a maximum jerk, maximum acceleration, maximum velocity, and a moving distance.

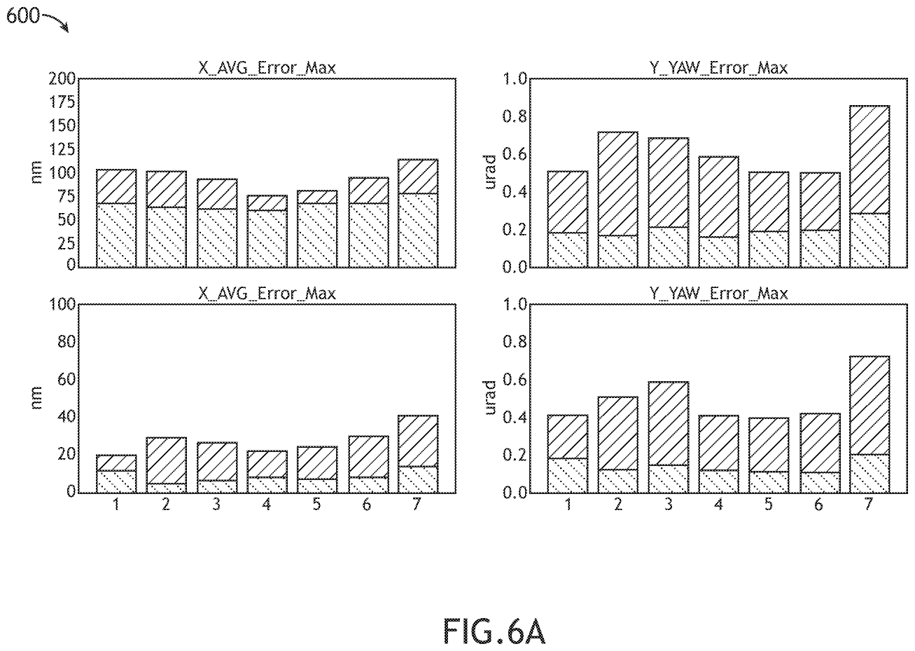

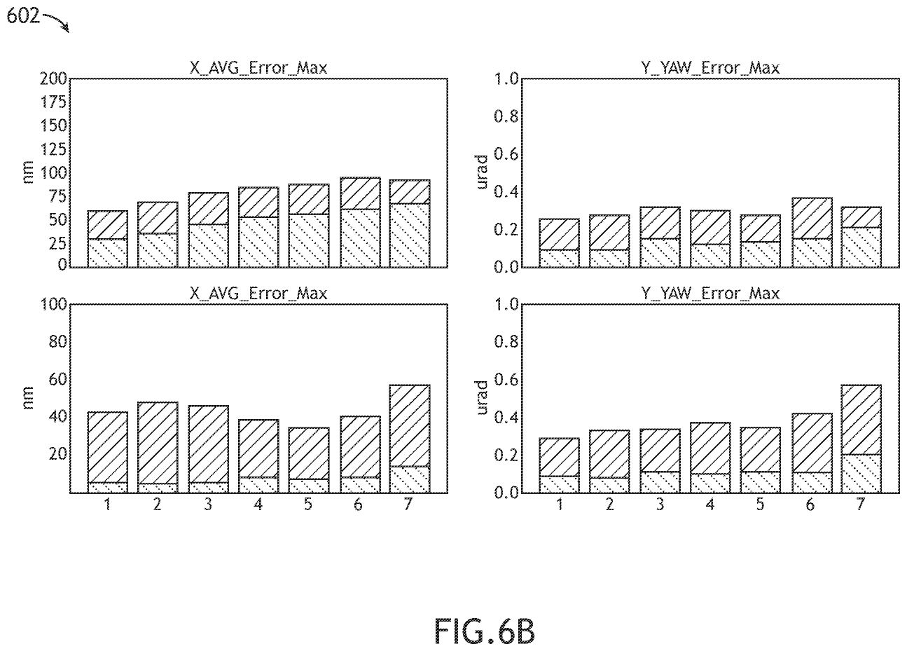

In embodiments, the acceleration versus time graph illustrated in FIG. 6 plots the acceleration for a given motion profile between a starting position and a target position, as may be defined by the system 100. As is generally understood, the plotted values shown may be mathematically derived from of at least one of a position or velocity chart, and they may also be used to derive at least one of a higher-order motion trajectory chart (e.g., snap, crackle, or pop).

In embodiments, the acceleration profile 202 may employ three of the seven profile stages including: constant acceleration (stage 2), constant velocity (stage 4), and constant deceleration (stage 6). This results in a trapezoidal profile shape depicted by the solid line in FIG. 2. The abrupt transitions between the constant acceleration/deceleration stages and the constant velocity stage may result in sharp corners between the one or more segments of the trapezoidal acceleration curve. Since the acceleration and deceleration phases of the trapezoidal profile for a standard 7-segment motion profile 204 are always constant, the acceleration curve for this profile steps abruptly between constant values, as illustrated by the solid line on the motion profile 204. Also, the jerk curve (representing the rate of change of acceleration/deceleration) pulses briefly during moments of transition (not plotted) and remains at zero when acceleration or deceleration remains constant.

In embodiments, since the trapezoidal profile of the standard 7-segment motion profile 204 always accelerates and decelerates at a constant rate without gradual transitioning to and from the constant velocity stage, the trapezoidal curve profile can traverse the distance between the current position and the target position relatively quickly. For example, the sudden transitions between acceleration/deceleration and constant (or zero) velocity can introduce undesirable mechanical turbulence in the system 100. Additionally, since the deceleration does not decrease gradually as the motion system approaches the target position, but instead maintains constant deceleration until the target position is reached before suddenly shifting to zero velocity, the trapezoidal motion profile has a high likelihood of overshooting the target position at the end of the initial traversal, requiring the controller 102 to apply a compensatory control signal to bring the load back to the target position. Therefore, in some embodiments, higher-order curved segments may be introduced into the acceleration profile 202 in order to smooth the transition between the one or more segments, which will help to reduce the mechanical turbulence exhibited in the system 100.

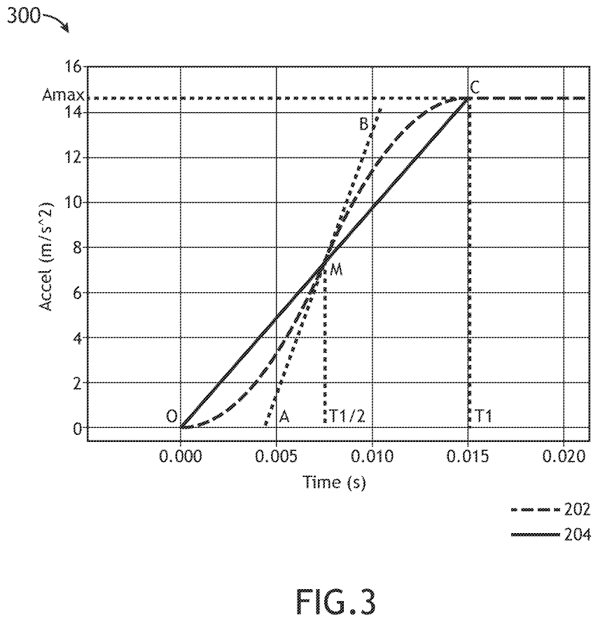

FIG. 3 illustrates a comparison 300 of a segment of the acceleration profile 202, generated by the motion profile system 100, with a segment of a standard 7-segment motion profile 204, in accordance with one or more embodiments of the present disclosure.

In embodiments, the motion profile system 100 may be configured to generate a motion profile to achieve a smoother acceleration profile 202 through the introduction of higher-order segments (e.g., snap, crackle, and pop), while preserving the standard 7-segment timing and position. For example, the one or more processors 104 of the controller 102 may be configured to divide each segment of the acceleration profile 202 into at least two sub-segments, as shown in FIG. 3. The division of the one or more segments and the introduction of the higher-order segments ensures a more gradual change at the terminal points of each segment, leading to a smoother overall trajectory.

In embodiments, as shown in FIG. 3, segment “OC” may be representative of the one or more segments of the acceleration profile 202. For example, segment OC may include a midpoint “M”, which is equidistant from both endpoints of segment OC. By way of another example, the one or more sub-segments may be divided from the one or more segments OC into at least a first sub-segment “OM” and a second sub-segment “MC”, where each sub-segment is a smooth transition curve. Further, a reference line “AB” may be configured to bisect OC at point M and have a slope greater than that of a segment OC of the standard 7-segment motion profile.

In embodiments, the first sub-segment of the curve OM may be defined by a function such that a starting point of the first sub-segment is tangent to the X-axis and an ending point of the first sub-segment is tangent to the reference line AB. Further, the second sub-segment may be defined by rotating the first sub-segment (e.g., 180 degrees) about point M.

It is noted herein that the smooth transition curve OM may be mathematically described by one or more various types of functions. For example, FIGS. 2-3 describe curve OM with the following polynomial function:

$$f ( t ) = {\sum }_{i = 0}^{N} {β}_{i} {t}^{i} \qquad ( 1 )$$

which satisfies the following boundary conditions:

$$\{ \begin{matrix}f ( 0 ) = 0 \\ f ( \frac{{T}_{1}}{2} ) = \frac{{A}_{max}}{2} \\ {f}^{′} ( \frac{{T}_{1}}{2} ) = λ {J}_{max} , λ > 1 \\ {f}^{′} ( 0 ) = 0\end{matrix} \qquad ( 2 )$$

Where λ is the slope ratio between reference line AB and segment OC.

It is noted that the polynomial function that was chosen is not limiting and a plurality of function types may be used to achieve the desired smoothness such as, but not limited to, a sigmoid function, tansig function, or sinusoid function.

In embodiments, the acceleration profile 202 of the system 100 may share one or more parameters with the standard 7-segment motion profile. For example, the acceleration profile 202 may share the same starting and ending points for each segment of the acceleration profile 202. By way of another example, the motion profile system 100 and the standard 7-segment motion profile may both maintain the same constant velocity at the same displacement, which is critical for wafer scanning processes. By way of another example, the compatibility of the motion profile system 100 may allow for its immediate adoption into existing products without the need to change any up-level software.

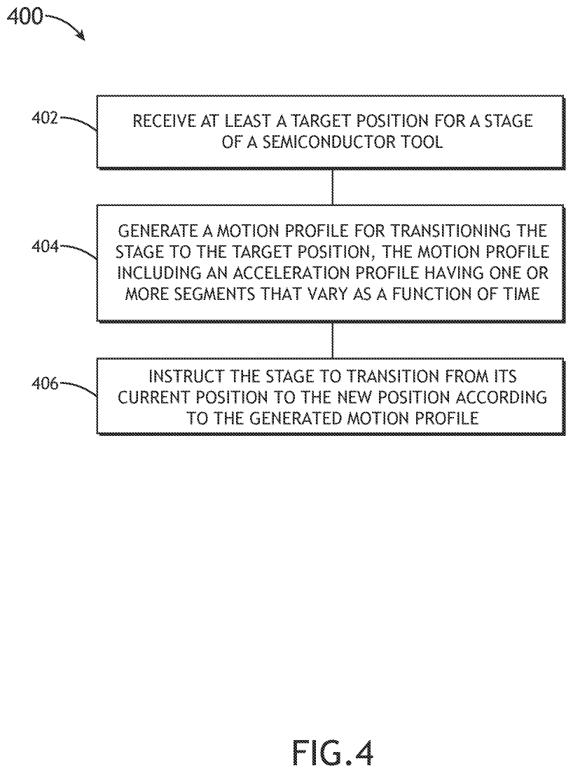

FIG. 4 is a flow diagram illustrating steps performed in a method 400 for generating a motion profile for a semiconductor stage 114, in accordance with one or more embodiments of the present disclosure. Applicant notes that the embodiments and enabling technologies described previously herein in the context of the motion profile system 100 should be interpreted to extend to the method 400. It is further noted, however, that the method 400 is not limited to the architecture of the motion profile system 100.

In embodiments, the method 400 includes a step 402 of receiving at least a target position for a stage 114 of a semiconductor tool 116. For example, the target position may represent the final position that the stage 114 is intended to reach after completion of the motion. By way of another example, a set of motion constraints may be defined including, but not limited to, limits on velocity, acceleration, deceleration, and jerk. The constraints may also include a definition of the sample time for the controller 102 used to control the system 100. By way of another example, a user interface device 108 may be configured to receive an input specifying at least one of the target position or the at least one defined constraint.

In embodiments, the motion trajectory of the motion profile system 100 may be divided into a plurality of segments. For example, at least one of the position, velocity, and/or acceleration of the motion profile, generated by the system 100, may vary during each segment.

In embodiments, the method 400 includes a step 404 of generating a motion profile for transitioning the stage 114 to at least the target position, the motion profile including an acceleration profile 202 that varies as a function of time. For example, the profile generator 110 may calculate this acceleration profile as a function of time for one or more segments of the motion profile.

In embodiments, the method 400 includes a step 406 of instructing the stage 114 to transition from its current position to a new position, in response to the generated motion profile. For example, the motion profile system 100 may be designed to control the motion of the stage 114 such that it follows the defined trajectory while adhering to the constraints imposed by at least one of the jerk, acceleration, and velocity limits. By way of another example, the controller 102 may transmit one or more control signals to a motor drive of the stage 114. In this regard, the motor drive may actuate the stage 114 based on the motion profile generated by the controller 102.

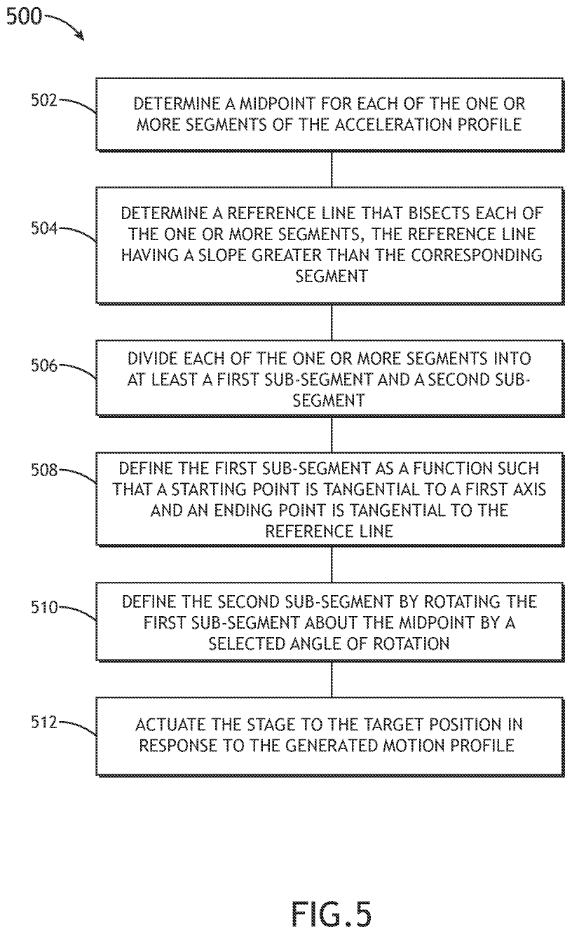

FIG. 5 is a flow diagram illustrating steps performed in a method for modifying one or more segments of the generated acceleration profile 202 for the semiconductor stage 114, in accordance with one or more embodiments of the present disclosure. Applicant notes that the embodiments and enabling technologies described previously herein in the context of the motion profile system 100 should be interpreted to extend to the method 500. It is further noted, however, that the method 500 is not limited to the architecture of the motion profile system 100.

In embodiments, the method 500 includes a step 502 of determining a midpoint of the one or more segments of the acceleration profile 202. For example, the one or more processors 104 may be configured to calculate the midpoint of a segment by dividing the duration of the corresponding segment in half.

In embodiments, the method 500 includes a step 504 of determining a reference line that bisects each of the one or more segments, the reference line having a slope that is greater than the corresponding segment. For example, the one or more processors 104 may be configured to determine the reference line by calculating the change in acceleration of the corresponding segment of the acceleration profile 202 at the midpoint.

In embodiments, the method 500 includes a step 506 of dividing each of the one or more segments into at least a first sub-segment and a second sub-segment. For example, the one or more processors 104 may be configured to define a starting point and ending point for a first sub-segment and a second sub-segment within the corresponding segment of the acceleration profile 202.

In embodiments, the method 500 includes a step 508 of defining the first sub-segment as a function such that a starting point of the first sub-segment is tangential to a first axis and an ending point is tangential to the reference line. For example, a plurality of function types may be used to achieve the desired smoothness such as, but not limited to, a polynomial function, sigmoid function, tansig function, or sinusoid function.

In embodiments, the method 500 includes a step 510 of defining the second sub-segment by rotating the first sub-segment about the midpoint of the segment by a selected angle of rotation. For example, the one or more processors 104 may be configured to rotate the first sub-segment of the acceleration profile 202 by 180 degrees about the midpoint.

In embodiments, the method 500 includes a step 512 of actuating the stage 114 to at least the target position. For example, the controller 102 may communicate the generated motion profile with a motor drive, which controls a motor that drives the stage 114.

FIGS. 6A-6B illustrate the performance metrics of the motion profile system 100 compared to a standard 7-segment motion profile, in accordance with one or more embodiments of the present disclosure.

It is noted herein that the motion profile system 100 of the present disclosure may demonstrate significant advantages over the traditional standard 7-segment motion profile, particularly in terms of achieving smoother transitions between each segment. This smooth transition not only enhances the motion control performance but also has a positive impact on the final position accuracy of the stage 114 of the semiconductor tool 116.

To illustrate the benefits of the motion profile system 100, a swath performance comparison is shown in FIGS. 6A-6B between the standard 7-segment motion profile and the motion profile system 100 measured under different swath speeds. The figures depict two sets of error bars: the brown bars represent the average error, while the blue bars represent the peak-to-peak error. The results clearly show that the motion profile system 100 exhibits improvements over the standard 7-segment method in terms of X, X_{yaw}, and Y_{yaw} position errors during the swath.

In particular, the motion profile system 100 shows remarkable enhancements in the X_{yaw} axis, with the X_{yaw} error reduced by approximately 50% compared to the standard 7-segment method. This reduction in error demonstrates the ability of the motion profile system 100 to minimize motion-induced coupling impacts to other motion axes, resulting in improved accuracy and stability during motion.

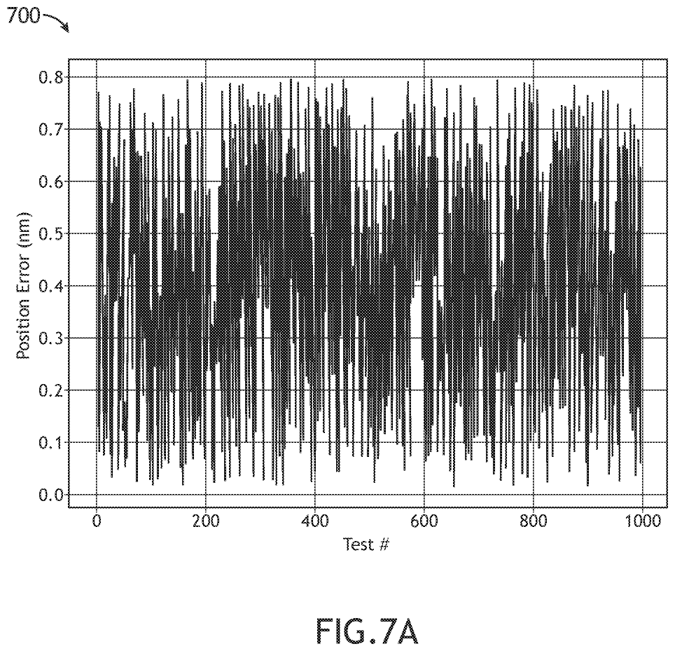

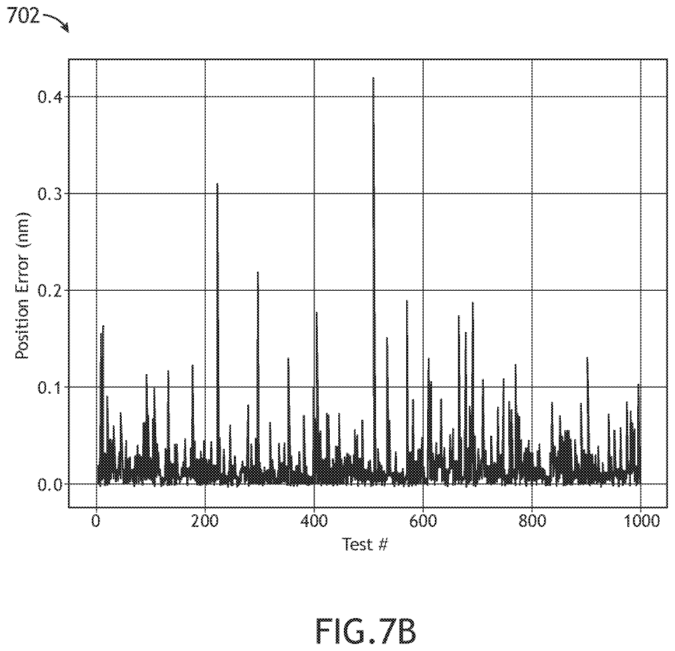

FIGS. 7A-7B illustrate a comparison of final position errors between the motion profile system 100 and a standard 7-segment motion profile, in accordance with one or more embodiments of the present disclosure. In embodiments, the standard 7-segment motion profile exhibits a wide-spread distribution of final position errors ranging from 0 to 0.8 nm. In contrast, the motion profile system 100 achieves significantly lower final position errors, with most of the errors confined to the range of 0 to 0.4 nm and a majority of data points below 0.1 nm.

These results indicate that the motion profile system 100 smoother motion trajectory and reduced vibrations lead to a more precise and accurate final position for the moving object. The narrower distribution of final position errors further demonstrates the reliability and consistency of the motion profile system 100, making it an ideal choice for high-precision applications where positional accuracy is critical.

Overall, the motion profile system 100 exhibits superior performance compared to the standard 7-segment method, with smoother transitions between segments, reduced motion-induced coupling impacts, and improved final position accuracy. These advantages make the motion profile system 100 a valuable and innovative motion control technique with the potential to revolutionize semiconductor manufacturing processes and other precision motion applications.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

As used throughout the present disclosure, the term “sample” generally refers to a substrate formed of a semiconductor or non-semiconductor material (e.g., a wafer, or the like). For example, a semiconductor or non-semiconductor material may include, but is not limited to, monocrystalline silicon, gallium arsenide, and indium phosphide.

It is believed that the present disclosure and many of its attendant advantages will be understood by the foregoing description, and it will be apparent that various changes may be made in the form, construction, and arrangement of the components without departing from the disclosed subject matter or without sacrificing all its material advantages. The form described is merely explanatory, and it is the intention of the following claims to encompass and include such changes. Furthermore, it is to be understood that the invention is defined by the appended claims.

What is claimed:

1. A system comprising:
a controller configured to modify a motion profile for a stage of a semiconductor tool, the controller comprising one or more processors configured to execute program instructions stored in memory, wherein the program instructions are configured to cause the one or more processors to:
receive at least a target position for the stage;
generate the motion profile for transitioning the stage to the target position, wherein the motion profile includes an acceleration profile having one or more segments that vary as a function of time,
wherein the one or more processors are further configured to modify the one or more segments of the acceleration profile by:
determining a midpoint for each of the one or more segments of the acceleration profile;
determining a reference line for each of the one or more segments, the reference line configured to bisect a corresponding segment and have a slope greater than the slope of the corresponding segment;
dividing each of the one or more segments into at least a first sub-segment and a second sub-segment;
defining the first sub-segment as a function such that a starting point is tangential to a first axis and an ending point is tangential to the reference line;
defining the second sub-segment by rotating the first sub-segment about the midpoint by a selected angle of rotation; and
actuating the stage to at least the target position in response to the generated motion profile.

2. The system of claim 1, wherein the one or more processors are further configured to generate the motion profile as a function of at least one defined constraint, wherein the at least one defined constraint includes at least one of a sample time, a velocity limit, an acceleration limit, a jerk limit, or a deceleration limit.

3. The system of claim 2, wherein the controller includes an interface device configured to receive an input specifying the at least one defined constraint.

4. The system of claim 1, wherein each sub-segment of the acceleration profile includes a smooth acceleration curve.

5. The system of claim 1, wherein the first sub-segment and the second sub-segment have half of a jerk time and half of an acceleration maximum value as the corresponding one or more segments.

6. The system of claim 1, wherein the second sub-segment is defined by rotating the first sub-segment about the midpoint for 180 degrees.

7. The system of claim 1, wherein one or more higher-order segments are introduced into the acceleration profile, the one or more higher-order segments including at least one of a snap, crackle, or pop.

8. A semiconductor characterization system, comprising:
a stage of a semiconductor tool;
a controller configured to modify a motion profile for the stage of the semiconductor tool, the controller comprising one or more processors configured to execute program instructions stored in memory, wherein the program instructions are configured to cause the one or more processors to:
receive at least a target position for the stage;
generate the motion profile for transitioning the stage to the target position, wherein the motion profile includes an acceleration profile having one or more segments that vary as a function of time,
wherein the one or more processors are further configured to modify the one or more segments of the acceleration profile by:
determining a midpoint for each of the one or more segments of the acceleration profile;
determining a reference line for each of the one or more segments, the reference line configured to bisect a corresponding segment and have a slope greater than the slope of the corresponding segment;
dividing each of the one or more segments into at least a first sub-segment and a second sub-segment;
defining the first sub-segment as a function such that a starting point is tangential to a first axis and an ending point is tangential to the reference line;
defining the second sub-segment by rotating the first sub-segment about the midpoint by a selected angle of rotation; and
actuating the stage to at least the target position in response to the generated motion profile.

9. The system of claim 8, wherein the one or more processors are further configured to generate the motion profile as a function of at least one defined constraint, wherein the at least one defined constraint includes at least one of a sample time, a velocity limit, an acceleration limit, a jerk limit, or a deceleration limit.

10. The system of claim 9, wherein the controller includes an interface device configured to receive an input specifying the at least one defined constraint.

11. The system of claim 8, wherein each sub-segment of the acceleration profile includes a smooth acceleration curve.

12. The system of claim 8, wherein the first sub-segment and the second sub-segment have half of a jerk time and half of an acceleration maximum value as the corresponding one or more segments.

13. The system of claim 8, wherein the second sub-segment is defined by rotating the first sub-segment about the midpoint for 180 degrees.

14. The system of claim 8, wherein one or more higher-order segments are introduced into the acceleration profile, the one or more higher-order segments including at least one of a snap, crackle, or pop.

15. A method for generating a motion profile, comprising:
receiving at least a target position for a stage of a semiconductor tool;
generating a motion profile for transitioning the stage to the target position, wherein the motion profile includes an acceleration profile having one or more segments that vary as a function of time,
modifying, via one or more processors, the one or more segments of the acceleration profile by:
determining a midpoint for each of the one or more segments of the acceleration profile;
determining a reference line for each of the one or more segments, the reference line configured to bisect a corresponding segment and have a slope greater than the slope of the corresponding segment;
dividing each of the one or more segments into at least a first sub-segment and a second sub-segment;
defining the first sub-segment as a function such that a starting point is tangential to a first axis and an ending point is tangential to the reference line;
defining the second sub-segment by rotating the first sub-segment about the midpoint by a selected angle of rotation; and
actuating the stage to at least the target position in response to the generated motion profile.

16. The method of claim 15, wherein the generating the motion profile comprises generating the motion profile as a function of at least one defined constraint, wherein the at least one defined constraint includes at least one of a sample time, a velocity limit, an acceleration limit, a jerk limit, or a deceleration limit.

17. The method of claim 16, wherein the generating the motion profile as a function of at least one defined constraint comprises receiving an input specifying the at least one defined constraint via an interface device.

18. The method of claim 15, wherein the modifying the one or more segments of the acceleration profile comprises defining a smooth acceleration curve for at least one of the first sub-segment and the second sub-segment.

19. The method of claim 15, wherein the defining the second sub-segment comprises rotating the first sub-segment about the midpoint for 180 degrees.

20. The method of claim 15, further comprising introducing one or more higher-order segments into the acceleration profile, the one or more higher-order segments including at least one of a snap, crackle, or pop.
